(19) United States
(12) Patent Application Publication
(10) Pub. No.: US 2007/0082446 A1
(43) Pub. Date: Apr. 12, 2007

(54) Methods for fabricating non-volatile memory cell array

(76) Inventors: Dominik Olligs, Dresden (DE); Thomas Mikolajick, Dresden (DE); Josef Willer, Riemerling (DE); Karl-Heinz Kuesters, Boxdorf (DE); Torsten Mueller, Dresden (DE)

Correspondence Address: SLATER & MATSIL LLP, 17950 PRESTON ROAD, SUITE 1000, DALLAS, TX, 75252, US

(21) Appl. No.: 11/246,908

(22) Filed: Oct. 7, 2005

(51) Int. Cl. H01L 21/336; H01L 21/76; H01L 21/302; H01L 21/461

(52) U.S. Cl. 438/264; 438/401; 438/736

(57) ABSTRACT

A method is provided for fabricating stacked non-volatile memory cells. A semiconductor wafer is provided having a plurality of diffusion regions forming buried bit lines. A charge-trapping layer and a conductive layer are deposited on the surface of the semiconductor wafer. Using a mask layer on top of the conductive layer, contact holes are formed wherein an insulating layer is formed. An etch stop layer is deposited on the surface of the semiconductor wafer. Above the etch stop layer, a dielectric layer is deposited and is patterned so as to form contact holes. Subsequently, the contact holes are enlarged through the etch stop layer and the insulating layer to the buried bit lines.

### TECHNICAL FIELD

The present invention relates to methods for producing memory cell arrays. In particular, the present invention relates to methods that are suitable to be used for planar EEPROMS for so-called “stand-alone” applications and for so-called “embedded” applications.

### BACKGROUND

One of the most important development aims in the field of memory cells is the realization of increasingly smaller memory cells, i.e., the use of increasingly smaller chip areas per bit stored. Up to now, it has been considered advantageous to realize compact cells by means of buried, i.e., diffused bit lines. However, bit lines implemented as diffusion areas become increasingly high ohmic as their structural size decreases, since the diffusion depth must be scaled as well, so as to counteract the risk of a punch through between neighboring bit lines. The problem arising in this connection is that high-ohmic bit lines permit only comparatively small cell blocks so that the utilization degree decreases and the advantage of the smaller memory cells, for which a higher process expenditure must be tolerated, diminishes.

One example of known memory cells with buried bit lines and a virtual-ground-NOR architecture is described in the article: “NROM: A Novel Localized Trapping, 2-Bit Nonvolatile Memory Cell”, Boaz Eitan et al, IEEE Electron Device Letters, Vol. 21, No. 11, November 2000, pp. 543-545, which is incorporated herein by reference. These concepts increase the resolution capabilities in semiconductor manufacturing. However, significant efforts and investments are needed to produce memories having the best possible resolution capabilities.

A further example of known memory cells is described in U.S. Pat. No. 6,686,242, which is incorporated herein by reference. A method for producing bit lines for a memory cell array comprises as a first step the step of providing a layer structure that comprises a substrate having transistor wells implanted in a surface thereof, a sequence of storage medium layers provided on the surface of the substrate, and a gate region layer provided on the sequence of storage medium layers. Bit line recesses, which extend down to the sequence of storage medium layers, are produced in the gate region layer. Subsequently, insulating spacer layers are produced on lateral surfaces of the bit line recesses, whereupon a source/drain implantation is executed in the area of the bit line recesses, after a complete or partial removal of the sequence of storage medium layers.

Following this, the substrate is exposed completely in the area of the bit line recesses, if this has not yet been done prior to the implantation. Subsequently, metallizations for producing metallic bit lines are produced on the exposed substrate, the metallizations being insulated from the gate region layer by the insulating spacer layers.

### SUMMARY OF THE INVENTION

In various embodiments, the present invention provides methods and devices that permit the realization of very compact memory cells.

According to a first aspect of the present invention, a method is provided for fabricating nonvolatile memory cells. A structured charge trapping layer is deposited on the surface of a semiconductor wafer. A plurality of gate lines are deposited on top of the structured charge trapping layer. An insulating spacer is deposited on the side walls of the plurality of gate lines. A plurality of buried bit lines are formed. Each of the buried bit lines is embedded in the substrate as a diffusion region. An insulating layer is deposited within the region between the plurality of gate lines and the structured charge trapping layer. An etch stop layer is deposited on top of the insulating layer. A dielectric layer is deposited on the top of the etch stop layer. The dielectric layer is etched to form contact holes ranging from the surface of the dielectric layer to the surface of the etch stop layer. The etch stop layer is etched to further enlarge the contact holes ranging from the surface of the dielectric layer to the surface of the insulating layer. The insulating layer is etched to further enlarge the contact holes ranging from the surface of the dielectric layer to the surface of the buried bit line. A contact plug is formed by filling the contact holes with a conductive plug material.

Yet another solution to the object is provided by a method for fabricating nonvolatile memory cells. A charge trapping layer is deposited on the surface of the semiconductor wafer. A conductive layer is deposited on top of the structured charge trapping layer. An insulating spacer is deposited on the side walls of the plurality of gate lines. A mask layer is deposited on top of the conductive layer. The mask layer is patterned so as to form a plurality of structural elements being arranged substantially parallel to each other. The conductive layer and the charge trapping layer are patterned using the plurality of structural elements as a hard mask so as to form gate lines being arranged between adjacent diffusion regions. A spacer oxide layer is deposited on the side walls of the plurality of gate lines, the structured charge trapping layer and the structural elements of the mask layer. Ions are implanted using the spacer oxide layer as a mask to form a plurality of buried bit lines within the substrate as diffusion regions. An insulating layer is deposited within the region between the plurality of gate lines and the structured charge trapping layer. The structural elements of the mask layer are removed. An etch stop layer is deposited on top of the insulating layer. A dielectric layer is deposited on the top of the etch stop layer. The dielectric layer is etched to form contact holes ranging from the surface of the dielectric layer to the surface of the etch stop layer. The etch stop layer is etched to further enlarge the contact holes ranging from the surface of the dielectric layer to the surface of the insulating layer. The insulating layer is etched to further enlarge the contact holes ranging from the surface of the dielectric layer to the surface of the buried bit line. A contact plug is formed by filling the contact holes with a conductive plug material.

Yet another solution to the object is provided by a method for fabricating nonvolatile memory cells. A structured charge trapping layer is deposited on the surface of the semiconductor wafer. A plurality of gate lines are deposited on top of the structured charge trapping layer. An insulating spacer is deposited on the side walls of the plurality of gate lines. A plurality of buried bit lines are formed. Each of the buried bit lines is embedded in the substrate as a diffusion region. A bit line insulating layer is deposited above the bit lines. An etch stop layer is deposited on top of the insulating layer. A dielectric layer is deposited on the top of the etch stop layer. The dielectric layer is etched to from contact holes ranging from the surface of the dielectric layer to the surface of the etch stop layer. The etch stop layer and the insulating layer are etched to further enlarge the contact holes ranging from the surface of the dielectric layer to the surface of the buried bit line. A contact plug is formed by filling the contact holes with a conductive plug material.

Yet another solution to the object is provided by a method for fabricating nonvolatile memory cells. A structured charge trapping layer is deposited on the surface of the semiconductor wafer. A plurality of gate lines is deposited on top of the structured charge trapping layer. An insulating spacer is deposited on the side walls of the plurality of gate lines. A plurality of buried bit lines are formed. Each of the buried bit lines is embedded in the substrate as a diffusion region. A bit line insulating layer is deposited above the bit lines covering the bit lines in a region between the gate lines. An etch stop layer is deposited on top of the insulating layer. The etch stop layer is etched to form a partially removed etch stop layer so as to uncover the top surface of bit line insulating layer. A dielectric layer is deposited on the top of the etch stop layer. The dielectric layer is etched to form contact holes ranging from the surface of the dielectric layer to the surface of the insulating layer. The insulating layer is etched to further enlarge the contact holes ranging from the surface of the dielectric layer to the surface of the buried bit line. A contact plug is formed by filling the contact holes with a conductive plug material.

Yet another solution to the object is provided by a method for fabricating nonvolatile memory cells. A structured charge trapping layer is deposited on the surface of the semiconductor wafer. A plurality of gate lines is deposited on top of the structured charge trapping layer. An insulating spacer is deposited on the side walls of the plurality of gate lines. A plurality of buried bit lines are formed. Each of the buried bit lines is embedded in the substrate as a diffusion region. A bit line insulating layer is deposited above the bit lines covering the bit lines in a region between the gate lines. An etch stop layer is deposited on top of the insulating layer. The etch stop layer is etched to form a partially removed etch stop layer having a smaller thickness on the top surface of the bit line insulating layer. A dielectric layer is deposited on the top of the etch stop layer. The dielectric layer is etched to form contact holes ranging from the surface of the dielectric layer to the surface of the etch stop layer. The partially removed etch stop layer and the insulating layer is etched to further enlarge the contact holes ranging from the surface of the dielectric layer to the surface of the buried bit line. A contact plug is formed by filling the contact holes with a conductive plug material.

### BRIEF DESCRIPTION OF THE DRAWINGS

The above features of the present invention will be more clearly understood from consideration of the following descriptions in connection with accompanying drawings in which:

FIG. 1 schematically depicts a detail of a memory cell array according to an embodiment of the invention in a top view;

FIGS. 2A to 2E schematically depict a memory cell array in a side view when applying the method steps according to an embodiment of the invention;

FIGS. 3A to 3C schematically depict a memory cell array in a side view when applying the method steps according to a further embodiment of the invention;

FIGS. 4A to 4B schematically depict a memory cell array in a side view when applying the method steps according to a further embodiment of the invention; and

FIGS. 5A to 5B schematically depict a memory cell array in a side view when applying the method steps according to a further embodiment of the invention.

### DETAILED DESCRIPTION OF ILLUSTRATIVE EMBODIMENTS

A presently preferred embodiment of the method for fabricating non-volatile memory cells having self-aligned bit line contacts and a non-volatile memory cell having self-aligned bit line contacts according to embodiments of the invention is discussed in detail below. It is appreciated, however, that the present invention provides many applicable inventive concepts that can be embodied in a wide variety of specific contexts. The specific embodiments discussed are merely illustrative of specific ways to apply the method and to apply the memory cell of the invention, and do not limit the scope of the invention.

In the following, embodiments of the method for fabricating non-volatile memory cells having self-aligned bit line contacts and a non-volatile memory cell having self-aligned bit line contacts are described with respect to NROM memories of the virtual ground architecture having a plurality of non-volatile memory cells.

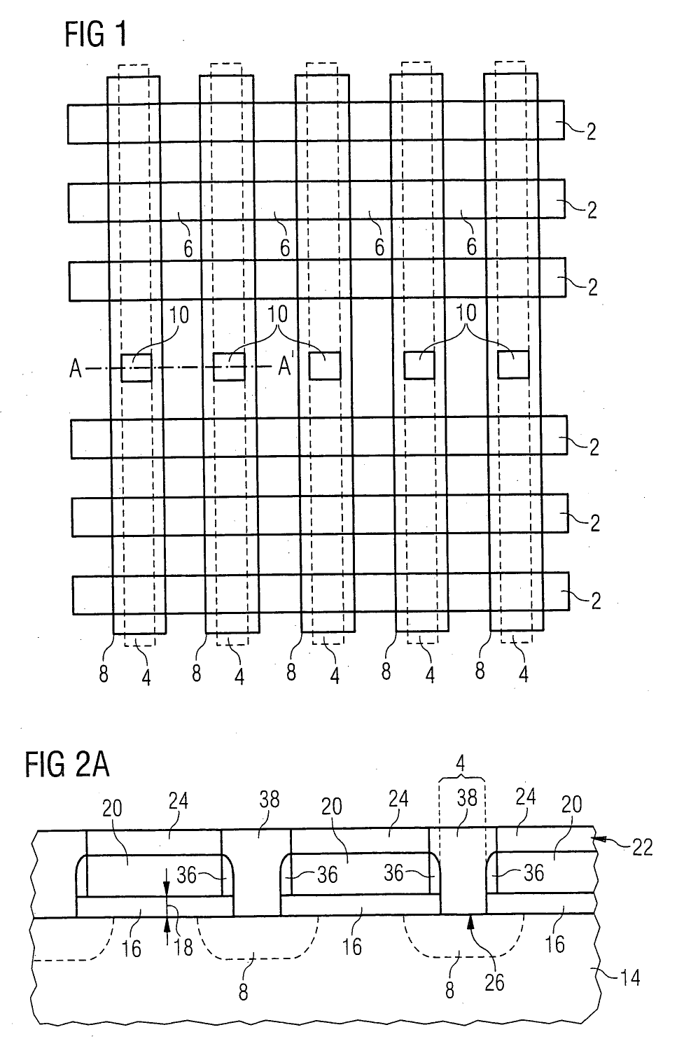

With respect to FIG. 1, a general layout of an NROM memory of the virtual ground architecture is shown in a top view. It should be appreciated that FIG. 1 merely serves as an illustration of fabricating non-volatile memory cells, i.e., the individual components shown in FIG. 1 are not true scale.

Before preferred embodiments for methods of producing a memory cell array will be explained in detail, the general arrangement of the resulting bit lines and word lines of a virtual-ground-NOR architecture will be described making reference to FIG. 1.

FIG. 1 schematically shows sections of several word lines 2 that extend at right angles to bit lines 8 so that the word lines 2 define together with the bit lines 8 a lattice structure. In the crossing area between word lines 2 and the space between bit lines 8, gate regions of the memory cell are located. In FIG. 1, the broken lines represent a geometrically reduced area 4 above buried bit lines 8, whereas the solid lines represent source/drain diffusion regions in which the buried bit lines 8 are formed.

In such a virtual-ground architecture respective memory cells 6 are arranged below the word lines 2 between the bit lines 8, as indicated in FIG. 1 for the second word line 2. Below the word lines several gate regions having a charge-trapping layer are provided in this area, whereas the diffusion regions, i.e., source/drain implantations arranged below the bit lines define the source drain regions of a respective cell.

As shown in FIG. 1, the buried bit lines 8 are contacted using bit line contacts 10. The bit line contacts 10 are used to provide a contact from an interconnecting layer disposed on a dielectric layer to the buried bit lines 8. According to embodiments of the present invention, the buried bit lines 8 are contacted using a bit line contact scheme employing a conductive plug. The conductive plug can be formed self-aligned to the bit lines 8, thus greatly reducing the risk of creating a short between adjacent bit lines 8 as compared to state-of-the-art non-self-aligned contacts.

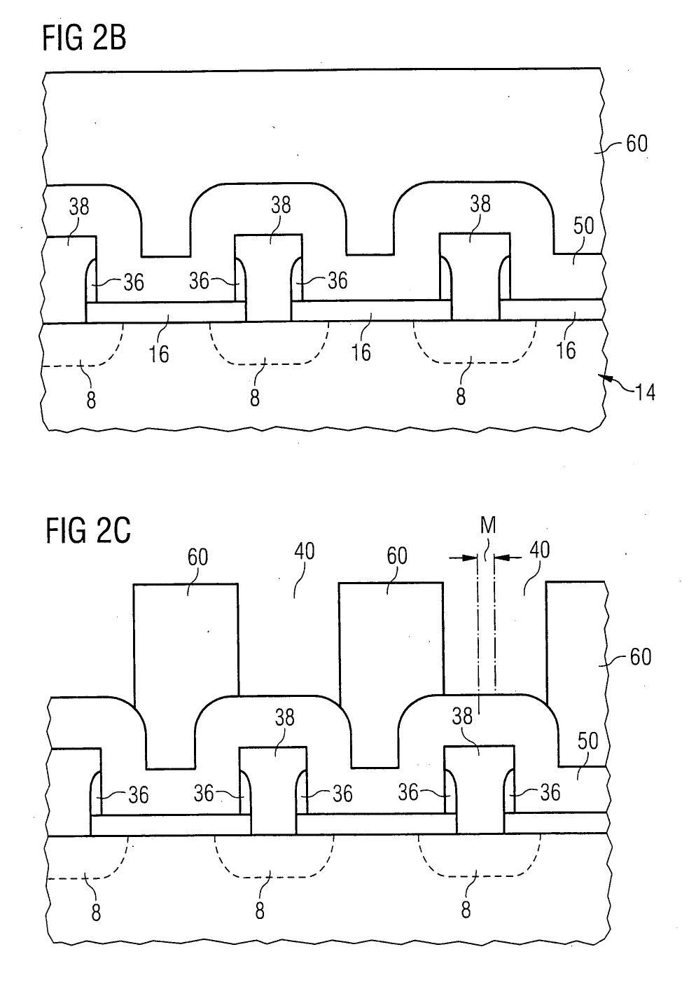

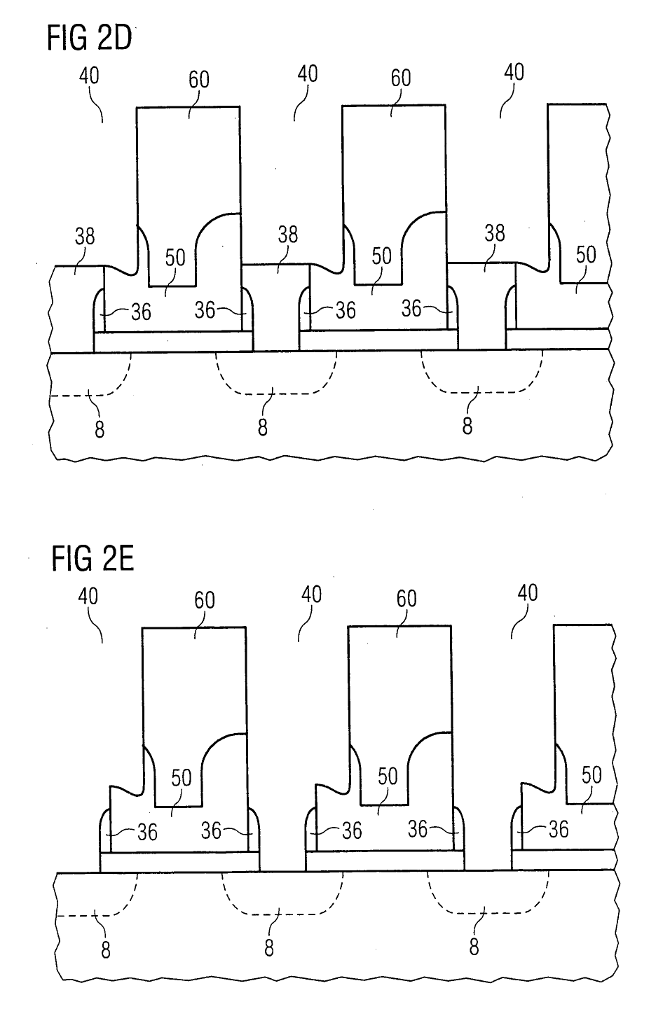

Referring now to FIG. 2A, a method for forming non-volatile memory cells is illustrated. In FIG. 2A, a semiconductor wafer 12 is shown in a perspective side view. The side view of FIG. 2A (and also of the following figures) is a cross-sectional side view along a plane perpendicular to the surface of semiconductor wafer 12 and parallel to word lines 2 through the bit line contacts 10, as indicated by line A-A′ in FIG. 1.

The semiconductor wafer 12 has a semiconductive substrate 14. Processing further includes conformably depositing a charge-trapping layer 16 on the semiconductive substrate 14. The step of conformably depositing the charge-trapping layer 16 includes depositing an oxide/nitride/oxide-layer stack. As an example, the oxide/nitride/oxide-layer stack has a thickness 18 of less than about 50 nm, preferably in a range between about 5 nm and about 30 nm.

Next, a conductive layer 20 is deposited on top of the charge-trapping layer 16. As an example, the conductive layer 20 is provided as a polysilicon layer. Subsequently, a mask layer 22 is deposited on top of the conductive layer 20. As an example, the step of depositing a mask layer 22 on the surface of the conductive layer 20 can be employed by depositing a nitride layer. In general, the mask layer 22 should have a high etching resistance against the materials of the semiconductive substrate 14, the charge-trapping layer 16 and the conductive layer 18.

In a next step, the mask layer 22 is lithographically patterned, so as to form structural elements 24 of the mask layer 22 on the surface of conductive layer 20. The patterning of the mask layer 22 includes depositing a resist layer on the surface of the mask layer 22 and lithographically patterning the resist layer to form a patterned resist layer. After removing the mask layer 22 outside the patterned resist layer by etching, the patterned resist layer can be removed.

Now, the structural elements 24 of the mask layer 22 are used as an etch mask in order to etch the conductive layer 20 and the charge-trapping layer 16. This etching step is performed selective to the patterned mask layer 22 by employing an anisotropic etching step, e.g., by reactive ion etching. Other suitable etching processes might be used as well.

As a result, gate lines are formed from the conductive layer 20 that cover the patterned charge-trapping layer 16 thus creating a region between the gate lines whereas the surface 26 of the semiconductive substrate 14 is substantially uncovered. It is, however, conceivable that residues, e.g., a thin bottom oxide layer remain on the surface 26 of the semiconductive substrate 14. Within this region, diffusion regions are formed from the surface 26 of the semiconductive substrate 14 into a certain depth, as shown in FIG. 2A. The diffusion regions have been shown with respect to FIG. 1 as bit lines 8.

A spacer 36 is deposited on the side walls of the gate lines 28, preferably as a silicon oxide layer.

In a next step, the oxide spacer layer 36 is used as an implantation mask. Using ions being selected with a proper energy the buried bit lines 8 are formed as an implanted region in the substrate 14 between the side walls of the oxide spacer layer 36. This step is performed to achieve optimized junction implants for the source/drain regions and thus the bit lines 8. Usually, this implantation is followed by a thermal anneal process sequence.

In a next step, an insulating layer 38 is deposited between the gate lines 28, as shown in FIG. 2A. Depositing the insulating layer 38 can be performed in the following way.

First, the insulating layer 38 is conformably deposited as a silicon dioxide layer. The insulating layer 38 covers the recesses between the gate lines 28 and the structural elements 24 of the mask layer 22. Next, the insulating layer 38 is removed from the top side of the hardmask 22 by employing a chemical mechanical polishing step.

In summary, etching and implanting of the semiconductor wafer 12 creates an insulating layer 38 that is arranged above the bit lines 8, as shown in FIG. 2A.

Processing continues by removing the structural elements 24 of the mask layer 22, e.g., by employing a wet-etch step. At that stage of the processing several other process steps might be envisaged, including deposition of a word line layer or layer stack and patterning the word line 2. Forming word lines 2 is known to a person skilled in the art and is, therefore, not described in further detail.

In a next step, a etch stop layer 50 is conformably deposited on the surface of the semiconductor wafer 12, as shown in FIG. 2B. The etch stop layer 50 is deposited as a silicon nitride layer, for example. The etch stop layer 50 has a thickness 18 of less than about 100 nm, preferably around 50 nm.

In a next step, a dielectric layer 60 is conformably deposited on the etch stop layer 50. The dielectric layer 60 is deposited as a BPSG layer, i.e., a boron phosphate silica glass layer. The dielectric layer 60 serves as a dielectric for an interconnecting metal layer, which is later deposited on the surface of the dielectric layer 60 (not shown in FIG. 2B).

In a next step, dielectric layer 60 is patterned so as to form contact holes 40 at those positions that are to be connected by the bit line contact 10. The patterning of the dielectric layer 60 includes depositing a resist layer on the surface of the dielectric layer 60, lithographically patterning the resist layer to form a patterned resist layer, and etching the dielectric layer 60 to form contact holes 40. Instead of using a lithographically patterned the resist layer, a hard mask layer can be used as well.

The resulting structure is shown in FIG. 2C. Etching the dielectric layer 60 can be performed by reactive ion-etching or any other possible process sequence.

In FIG. 2C, a possible mismatch during patterning of the dielectric layer 60 is indicated by the difference M to a nominal position being centered above the bit line 4. According to embodiments of the invention, the mismatch does not influence the underlying structure below the etch stop layer 50.

Next, the contact holes 40 are further enlarged in a direction perpendicular to the surface of semiconductor wafer 12, as shown in FIG. 2D. Accordingly, the etch stop layer 50 is etched and the contact holes 40 now range from the surface of dielectric layer 60 to the surface of insulating layer 38. Etching of the etch stop layer 50 can be performed by reactive ion-etching.

In a first possible process sequence, the etch stop layer 50 is etched for a given time period so as to completely etch the etch stop layer 50 in the region of the contact holes 40. In a second possible process sequence, the etch stop layer 50 is etched and the resulting etched materials are monitored in order to determine an end point when reaching insulating layer 38.

In a next step, the contact holes 40 are further enlarged in a direction perpendicular to the surface of semiconductor wafer 12, as shown in FIG. 2E. This is performed by etching the insulating layer 38. The contact holes 40 now range from the surface of dielectric layer 60 to the surface of the bit lines 8. Etching of the insulating layer 38 can be performed by reactive ion-etching as well.

Processing further continues by depositing a contact plug material in the contact holes 40 above the bit lines 8. The contact holes 40 are then filled with conductive material so as to form a contact plug 10 at certain positions within the memory cell array, as shown in FIG. 1. This may include the formation of titanium, titanium nitride, or a titanium-titanium nitride layer stack, as is known in the art.

According to the process sequence described above, contacting the buried bit line 8 is performed using a self-aligned scheme. The self-aligned processing greatly reduces the risk of accidentally contacting elements surrounding the bit lines 8 by using the self alignment of the insulating layer 38 and the different etching selectivity of insulating layer 38, etch stop layer 50 and dielectric layer 60.

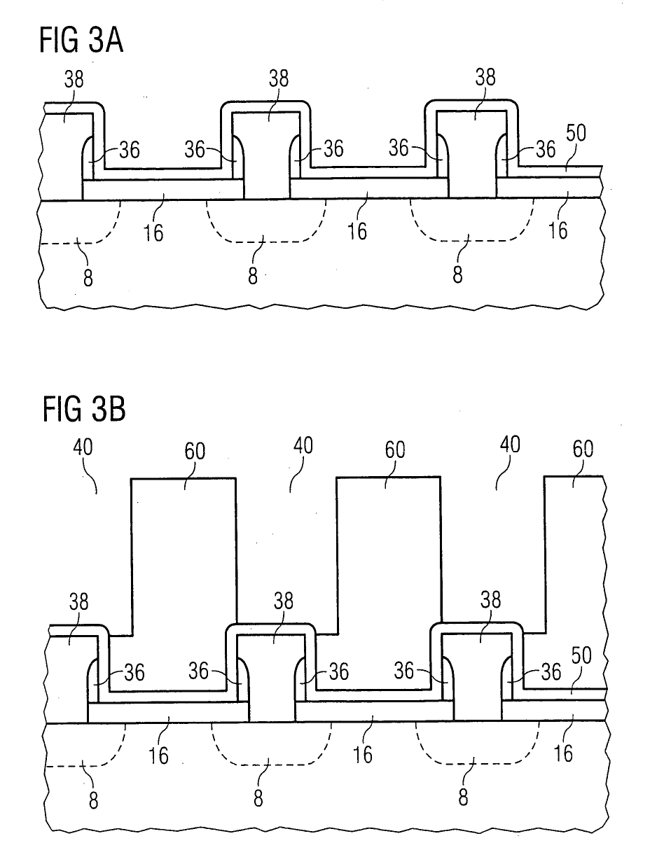

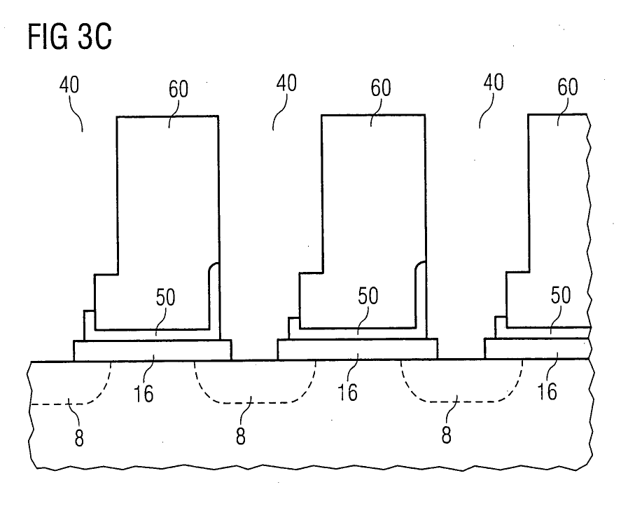

With respect to FIGS. 3A to 3C, a further embodiment of the invention is shown. Processing according the embodiment described below uses several process steps being similar to the embodiment as described with respect to FIGS. 1 and 2. As will become apparent, the main difference to the previously described embodiment is that the insulating layer 38 and the etch stop layer 50 are etched simultaneously.

Referring now to FIG. 3A, processing according to FIG. 2A has already been performed on semiconductor wafer 12. The step of depositing an insulating layer 38 between the gate lines is performed in the following alternative embodiments. First, the insulating layer 38 is conformably deposited as a silicon oxynitride layer. Afterwards a chemical-mechanical polishing step is performed. Alternatively, the insulating layer 38 is performed using an oxide based process sequence that allows void-free filling of the gap between the gate lines.

In general, the insulating layer 38 has a high etching selectivity to the later applied dielectric layer and the material of insulating layer 38 is chosen accordingly.

Processing continues by removing the structural elements 24 of the mask layer 22, e.g., by employing a wet-etch step. At that stage, forming word lines 2 can be performed.

In a next step, the etch stop layer 50 is conformably deposited on the surface of the semiconductor wafer 12, as shown in FIG. 3A. The etch stop layer 50 is deposited either as a silicon nitride layer. The etch stop layer 50 has a thickness 18 of less than about 100 nm, preferably around 30 to 50 nm.

In a next step, a dielectric layer 60 is conformably deposited on the etch stop layer 50. Again, the dielectric layer 60 is deposited as a BPSG layer. In a next step, dielectric layer 60 is patterned, so as to form contact holes 40 at those positions that are to be connected by the bit line contact 10. The patterning of the dielectric layer 60 is either performed lithographically or using a hardmask layer utilizing the different etching selectivity between different layer materials.

The resulting structure is shown in FIG. 3B. Etching the dielectric layer 60 can be performed by reactive ion-etching or any other possible process sequence.

Next, the contact holes 40 are further enlarged in a direction perpendicular to the surface of semiconductor wafer 12, as shown in FIG. 3C. Accordingly, the etch stop layer 50 and the insulating layer 38 are etched. The contact holes 40 now extends from the surface of dielectric layer 60 to the surface of the bit lines 8. Etching of the insulating layer 38 can be performed by reactive ion-etching as well.

Processing further continues by depositing a contact plug material in the contact holes 40 above the bit lines 8. The contact holes 40 are then filled with conductive material so as to form a contact plug 10 at certain positions within the memory cell array, as shown in FIG. 1. This may include the formation of titanium, titanium nitride, or a titanium-titanium nitride layer stack, as is known in the art.

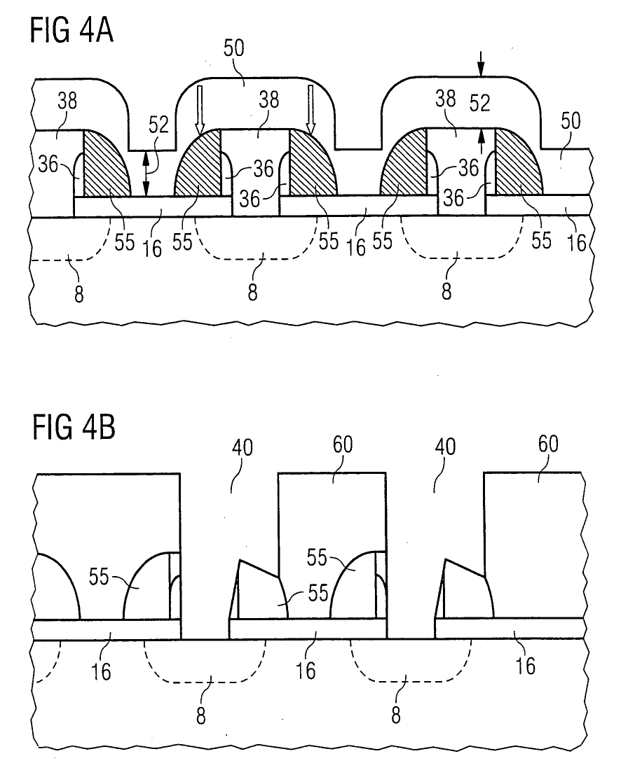

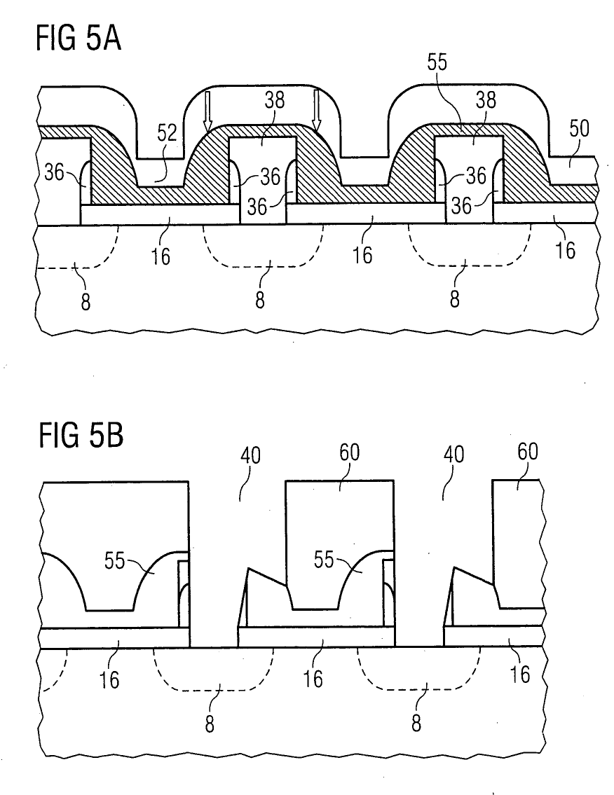

With respect to FIGS. 4A to 4B and to FIGS. 5A to 5B, further embodiments of the invention are shown. The main difference to the embodiments described above is that the etch stop layer 50 is etched before applying the dielectric layer 60. In the following descriptions of the further embodiments, only the different processing steps are outlined. Accordingly, the following description makes reference to the embodiments of FIG. 1, FIGS. 2A to 2E and to FIGS. 3A to 3C, where appropriate.

After removing the structural elements 24 of the mask layer 22 and forming of word lines 2 the etch stop layer 50 is conformably deposited on the surface of the semiconductor wafer 12, as shown in FIG. 4A. The etch stop layer 50 is deposited as a silicon nitride layer. The etch stop layer 50 has a thickness of less than about 100 nm, preferably around 30 to 50 nm.

In a next step, the etch stop layer 50 is etched so as to release the surface of the insulating layer 38. At that point a partially removed etch stop layer 55 is formed, as shown in FIG. 4A. The difference in thickness is indicated by the arrows in FIG. 4A and is such that the surface of the insulating layer 38 is released.

In a next step, a dielectric layer 60 is conformably deposited on the partially removed etch stop layer 55 and on the released surface of the insulating layer 38. Again, the dielectric layer 60 can be deposited as a BPSG layer.

In a next step, dielectric layer 60 is patterned, so as to form contact holes 40 at those positions that are to be connected by the bit line contact 10. The patterning of the dielectric layer 60 is either performed lithographically or using a hardmask layer. The resulting structure is shown in FIG. 4B.

Next, the contact holes 40 are further enlarged in a direction perpendicular to the surface of semiconductor wafer 12, as shown in FIG. 4B. Accordingly, the etch stop layer 50 and the insulating layer 38 are removed in the contact holes 40. The contact holes 40 now extends from the surface of dielectric layer 60 to the surface of the bit lines 8.

Subsequently, further metal interconnecting layers can be provided as described previously.

Referring now to FIG. 5A, the etch stop layer 50 is conformably deposited on the surface of the semiconductor wafer 12. The etch stop layer 50 is deposited as a silicon nitride layer. The etch stop layer 50 has a thickness of less than about 100 nm, preferably around 30 to 50 nm.

In a next step, the etch stop layer 50 is thinned by etching. Opposed to the embodiment of FIG. 4a, the surface of the insulating layer 38 is not fully uncovered. At that point, a partially removed etch stop layer 55 is formed, as shown in FIG. 5A. The difference in thickness is indicated by the arrows in FIG. 5A and is such that the surface of the insulating layer 38 is still covered by a thin etch stop layer 55.

In a next step, a dielectric layer 60 is conformably deposited on the partially removed etch stop layer 55. Again, the dielectric layer 60 can be deposited as a BPSG layer.

In a next step, dielectric layer 60 is patterned, so as to form contact holes 40 at those positions that are to be connected by the bit line contact 10. The patterning of the dielectric layer 60 is either performed lithographically or using a hardmask layer. The resulting structure is shown in FIG. 5B.

Next, the contact holes 40 are further enlarged in a direction perpendicular to the surface of semiconductor wafer 12, as shown in FIG. 5B. Accordingly, the etch stop layer 50 and the insulating layer 38 are removed in the contact holes 40. The contact holes 40 now range from the surface of dielectric layer 60 to the surface of the bit lines 8.

Subsequently, further metal interconnecting layers can be provided as described previously.

The further embodiments of the invention as shown with respect to FIGS. 4A to 4B and to FIGS. 5A to 5B, allow a simple processing sequence.

Having described embodiments for a method for fabricating non-volatile memory cells and non-volatile memory cells, it is noted that modifications and variations can be made by persons skilled in the art in light of the above teachings. It is, therefore, to be understood that changes may be made in the particular embodiments of the invention disclosed, which are within the scope and spirit of the invention as defined by the appended claims.

Having thus described the invention with the details and the particularity required by the patent laws, what is claimed and desired to be protected by Letters Patent is set forth in the appended claims.

What is claimed is:

1. A method for fabricating nonvolatile memory cells, the method comprising:
providing a semiconductor wafer having a semiconductive substrate;
depositing a structured charge-trapping layer over the surface of said semiconductor wafer;
depositing a plurality of gate lines over said structured charge-trapping layer;
depositing an insulating spacer over side walls of said plurality of gate lines;
forming a plurality of buried bit lines, wherein each of said buried bit lines is embedded in said semiconductive substrate;
depositing an insulating layer within the region between said plurality of gate lines and said structured charge-trapping layer;
depositing an etch stop layer over said insulating layer;
depositing a dielectric layer over said etch stop layer;
etching said dielectric layer to form contact holes extending from the surface of said dielectric layer to the surface of said etch stop layer;
etching said etch stop layer so that said contact holes extend from the surface of said dielectric layer to the surface of said insulating layer;
etching said insulating layer so that said contact holes ranging from the surface of said dielectric layer to the surface of said buried bit line; and
forming a contact plug by filling said contact holes with a conductive plug material.

2. The method according to claim 1, further comprising depositing an structuring a hardmask prior to the step of etching said dielectric layer, the hardmask serving as an etch mask during the step of etching said dielectric layer.

3. The method according to claim 1, wherein etching said dielectric layer comprises reactive ion etching.

4. The method according to claim 1, wherein etching said etch stop layer comprises etching with end point detection.

5. The method according to claim 1, wherein etching said etch stop layer comprises etching for a predetermined time so as to fully remove said etch stop layer within said contact hole.

6. The method according to claim 1, wherein etching said insulating layer comprises etching for a predetermined time so as to fully remove said insulating layer within said contact hole.

7. A method for fabricating nonvolatile memory cells, the method comprising:
providing a semiconductor wafer having a semiconductive substrate;
depositing a charge-trapping layer over the surface of said semiconductor wafer;
depositing a conductive layer over said structured charge trapping layer;
depositing a mask layer over said conductive layer;
patterning said mask layer so as to form a plurality of structural elements being arranged substantially parallel to each other;
patterning said conductive layer and said charge-trapping layer using said plurality of structural elements as a hardmask so as to form gate lines;
depositing a spacer oxide layer on the side walls of said plurality of gate lines, said structured charge-trapping layer and said structural elements of said mask layer;
implanting ions using said spacer oxide layer as a mask to form a plurality of buried bit lines within said substrate as diffusion regions;
depositing an insulating layer within the region between said plurality of gate lines and said structured charge-trapping layer;
removing said structural elements of said mask layer;
depositing an etch stop layer over said insulating layer;
depositing a dielectric layer over said etch stop layer;
etching said dielectric layer to form contact holes extending from the surface of said dielectric layer to the surface of said etch stop layer;
etching said etch stop layer so that said contact holes ranging from the surface of said dielectric layer to the surface of said insulating layer;
etching said insulating layer so that said contact holes extend from the surface of said dielectric layer to the surface of said buried bit line; and
forming a contact plug by filling said contact holes with a conductive plug material.

8. The method according to claim 7, wherein the step of depositing a mask layer over the surface of said conductive layer comprises conformably depositing a nitride layer as said mask layer.

9. The method according to claim 7, wherein patterning said mask layer comprises:
depositing a resist layer over the surface of said mask layer;
lithographically patterning said resist layer to form a patterned resist layer;
removing said mask layer outside said patterned resist layer by etching; and
removing said patterned resist layer.

10. The method according to claim 7, wherein depositing said charge-trapping layer comprises depositing an oxide/nitride/oxide-layer stack as said charge-trapping layer.

11. The method according to claim 10, wherein said oxide/nitride/oxide-layer stack has a thickness of less than about 50 nm.

12. The method according to claim 10, wherein said oxide/nitride/oxide-layer stack has a thickness in a range between about 5 nm and about 15 nm.

13. The method according to claim 7, wherein prior to the step of depositing an etch stop layer the following steps are performed:
depositing a further conductive layer over the surface of said semiconductive wafer; and
patterning said further conductive layer so as to form a plurality of word lines, said word lines being arranged substantially perpendicular to said bit lines and having a certain distance to the region of said contact fill material within first contact hole.

14. The method according to claim 13, wherein after the step of depositing said further conductive layer, the following steps are performed:
conformably depositing a metal containing layer over the surface of said further conductive layer; and
patterning said metal containing layer so as to cover the top side of said word lines.

15. The method according to claim 14, wherein the step of depositing a metal containing layer comprises depositing a layer that includes tungsten.

16. The method according to claim 15, wherein the step of depositing a metal-containing layer comprises depositing a tungsten silicon alloy.

17. The method according to claim 14, wherein said metal-containing layer has a thickness of less than about 50 nm.

18. The method according to claim 17, wherein said metal-containing layer has a thickness in a range between 5 about nm and 15 about nm.

19. The method according to claim 7, wherein said conductive layer is deposited as a polysilicon layer.

20. The method according to claim 13, wherein said further conductive layer is deposited as a polysilicon layer.

21. The method according to claim 7, wherein depositing an insulating layer comprises conformably depositing a silicon dioxide layer.

22. The method according to claim 21, wherein etching said insulating layer comprises anisotropically etching said insulating layer.

23. The method according to claim 21, wherein depositing a dielectric layer comprises conformably depositing a boron-phosphate silica glass (BPSG) layer.

24. The method according to claim 21, wherein depositing an etch stop layer comprises conformably depositing a silicon nitride layer.

25. The method according to claim 24, wherein said etch stop layer has a thickness of less than about 100 nm.

26. The method according to claim 25, wherein said etch stop layer has a thickness in a range between about 20 nm and about 60 nm.

27. A method for fabricating a nonvolatile memory cell, the method comprising:
providing a semiconductor wafer having a semiconductive substrate;
depositing a structured charge-trapping layer over said semiconductor wafer;
depositing a plurality of gate lines over said structured charge-trapping layer;
depositing an insulating spacer over the side walls of a plurality of gate lines;
forming a plurality of buried bit lines, wherein each of said buried bit lines is partially embedded in said substrate as a diffusion region;
depositing a bit line insulating layer above said bit lines;
depositing an etch stop layer over said insulating layer;
depositing a dielectric layer over said etch stop layer;
etching said dielectric layer to form contact holes extending from the surface of said dielectric layer to the surface of said etch stop layer;
etching said etch stop layer and said insulating layer so that said contact holes extend from the surface of said dielectric layer to the surface of said buried bit line; and
forming a contact plug by filling said contact holes with a conductive plug material.

28. The method according to claim 27, wherein depositing a bit line insulating layer above said bit lines comprises depositing a material as said bit line insulating layer having a high etching selectivity with respect to said dielectric layer.

29. The method according to claim 27, wherein depositing said dielectric layer comprises depositing a boron-phosphate silica glass layer.

30. The method according to claim 29, wherein the step of etching said insulating layer is performed selectively by forming an oxide-nitride layer on said insulating layer.

31. The method according to claim 27, wherein depositing an etch stop layer comprises conformably depositing a silicon nitride layer.

32. A method for fabricating nonvolatile memory cells, the method comprising:
providing a semiconductor wafer having a semiconductive substrate;
depositing a structured charge-trapping layer over a surface of said semiconductor wafer;
depositing a plurality of gate lines on top of said structured charge-trapping layer;
depositing an insulating spacer on the side walls of said plurality of gate lines;
forming a plurality of buried bit lines, wherein each of said buried bit lines is embedded in said substrate as a respective one of a diffusion region;
depositing a bit line insulating layer above said bit lines covering said bit lines in a region between said gate lines;
depositing an etch stop layer on top of said insulating layer;
etching said etch stop layer to form a partially removed etch stop layer so as to uncover said top surface of bit line insulating layer;
depositing a dielectric layer on the top of said etch stop layer;
etching said dielectric layer to from contact holes extending from the surface of said dielectric layer to the surface of said insulating layer;
etching said insulating layer to further enlarge said contact holes extending from the surface of said dielectric layer to the surface of said buried bit line; and
forming a contact plug by filling said contact holes with a conductive plug material.

33. A method for fabricating nonvolatile memory cells, the method comprising:
providing a semiconductor wafer having a semiconductive substrate;
depositing a structured charge-trapping layer on the surface of said semiconductor wafer;
depositing a plurality of gate lines on top of said structured charge-trapping layer;
depositing an insulating spacer on the side walls of said plurality of gate lines;
forming a plurality of buried bit lines, wherein each of said buried bit lines is embedded in said substrate as a diffusion region;
depositing a bit line insulating layer above said bit lines covering said bit lines in a region between said gate lines;
depositing an etch stop layer on top of said insulating layer;
etching said etch stop layer to form a partially removed etch stop layer having a smaller thickness on the top surface of said bit line insulating layer;
depositing a dielectric layer on the top of said etch stop layer;
etching said dielectric layer to from contact holes extending from the surface of said dielectric layer to the surface of said etch stop layer;
etching said partially removed etch stop layer and said insulating layer to further enlarge said contact holes extending from the surface of said dielectric layer to the surface of said buried bit line; and
forming a contact plug by filling said contact holes with a conductive plug material.

34. The method according to claim 33, wherein depositing a bit line insulating layer above said bit lines comprises depositing a material as said bit line insulating layer having a high etching selectivity with respect to said dielectric layer.

35. The method according to claim 34, wherein depositing said dielectric layer comprises depositing a boron-phosphate silica glass layer.

36. The method according to claim 34, wherein etching said insulating layer is performed selectively by forming an oxide-nitride layer on said insulating layer.

37. The method according to claim 34, wherein depositing an etch stop layer comprises conformably depositing a silicon nitride layer.
